(19) United States
(12) Patent Application Publication
(10) Pub. No.: US 2019/0242931 A1
(43) Pub. Date: Aug. 8, 2019

(54) APPLIANCE MONITORING SYSTEM AND METHOD

(71) Applicant: Steven G. Butcher, Bloomington, IN (US)

(72) Inventor: Steven G. Butcher, Bloomington, IN (US)

(21) Appl. No.: 16/270,785

(22) Filed: Feb. 8, 2019

Related U.S. Application Data
(60) Provisional application No. 62/628,257, filed on Feb. 8, 2018.

(51) Int. Cl. G01R 19/165; G08B 21/18

(52) U.S. Cl. CPC G01R 19/16571; G08B 21/182

(57) ABSTRACT

A system for detecting changes in an operating state of an appliance includes a plug-through monitoring device and an alarm structured to produce an alarm notification. The plug-through monitoring device has an electrical monitoring mechanism for monitoring electrical current draw by the appliance from a power source. The plug-through monitoring device including a sensor, a processor, and a memory, and has a transmitter coupled with the electrical monitoring mechanism. The transmitter is coupled with the alarm.

### TECHNICAL FIELD

The present disclosure relates generally to monitoring electrical current draw by household appliances and, more particularly, to monitoring changes in electrical current draw indicative of a change in an operating state of the appliance.

### BACKGROUND

A modern dwelling is typically full of a great many number of electrically-powered household appliances that facilitate homeowners' day-to-day tasks. Many of these appliances have long been a ubiquitous presence in homes, such as refrigerators, washers, dryers, dishwashers, ovens, toasters, coffee makers, slow cookers, irons, and countless others. Use of many of these appliances is relatively passive while the appliance is in use in that the appliance cycles, heats up, or otherwise runs without the need for the user engagement, and then shuts down when complete. For example, dryers, dishwashers, coffee makers, toasters, and slow cookers dry, wash, brew, toast, and cook, respectively, without any participation by the user. Similarly, electric ovens, irons, and other appliances typically must be preheated before use. During these periods, the user is not required to, and typically does not, monitor the appliance while in use in any conventional sense.

These and other appliances offer the convenience of not only making the task itself easier but also of giving the user time to complete other tasks. For instance, perhaps a user will fix her breakfast while waiting for her iron to heat up while getting ready for work in the morning, or maybe a user will watch television or do some gardening in the back yard while his dishwasher is running. While these appliances do afford users the flexibility to perform multiple tasks concurrently, these conveniences do not come without some drawbacks. Often users become consumed or distracted by the tasks their appliances freed them up to do, causing the user to forget the appliance is running. The consequences of forgetting about running appliances are often merely an inconvenience, such as letting clean, dry clothes wrinkle in a dryer or a user letting his freshly toasted bagel cool, but can also be more severe as may be the case if a user forgets he is preheating his electric oven, electric stove, or iron.

One attempt to address such problems is disclosed in United States Patent Application No. 20110246124 to Lill et al. (“Lill”). Lill discloses a remote appliance monitoring system that includes a monitoring apparatus and an alarm apparatus. The monitoring apparatus is apparently structured to determine an operating state of an appliance by monitoring movement or vibration of the appliance. When the monitoring apparatus determines the appliance has completed a cycle, a wireless signal is transmitted to the alarm apparatus, at which point an audio or visual alarm is produced. While Lill's disclosure may potentially be useful in certain application, improved or alternative strategies for monitoring a wider array of appliances remain desirable.

### SUMMARY OF THE INVENTION

In one aspect a method for monitoring an operating state of an appliance includes detecting an increase in current draw indicative of a first change in the operating state, detecting a decrease in current draw indicative of a second change in the operating state that is indicative of the appliance completing a task, monitoring current draw after detecting the decrease in current draw, and outputting an alarm signal responsive to the second change in the operating state.

In another aspect, a system for detecting changes in an operating state in an appliance includes a plug-through device positioned in electric series between the appliance and a power source, the plug-through device including an electrical monitoring mechanism structured to detect a current draw pattern indicative of current draw by the appliance, and output an alarm signal responsive to the current draw pattern. The system also includes an alarm having an alarm notification mechanism that activates responsive to an alarm signal.

In still another aspect, a plug-through device for determining an operating state of an appliance includes an electric monitoring mechanism structured to detect a change in current draw by the appliance indicative of a change in the operating state of the appliance, and to output an alarm signal responsive to the change in current draw. The plug-through device also includes a transmitter structured to transmit the alarm signal.

### BRIEF DESCRIPTION OF THE DRAWINGS

FIG. 1 is a block diagram of an appliance monitoring system, according to one embodiment;

FIG. 2 is a partially sectioned diagrammatic view of a portion of an appliance monitoring system, according to one embodiment;

FIG. 3 is a diagrammatic view of a plug-through monitoring device, according to one embodiment;

FIG. 4 is a flowchart illustrating example process and control logic, according to one embodiment;

FIG. 5 is graph illustrating exemplary current draw by an appliance, according to one embodiment; and

FIG. 6 is a graph illustrating exemplary current draw by an appliance, according to one embodiment.

### DETAILED DESCRIPTION

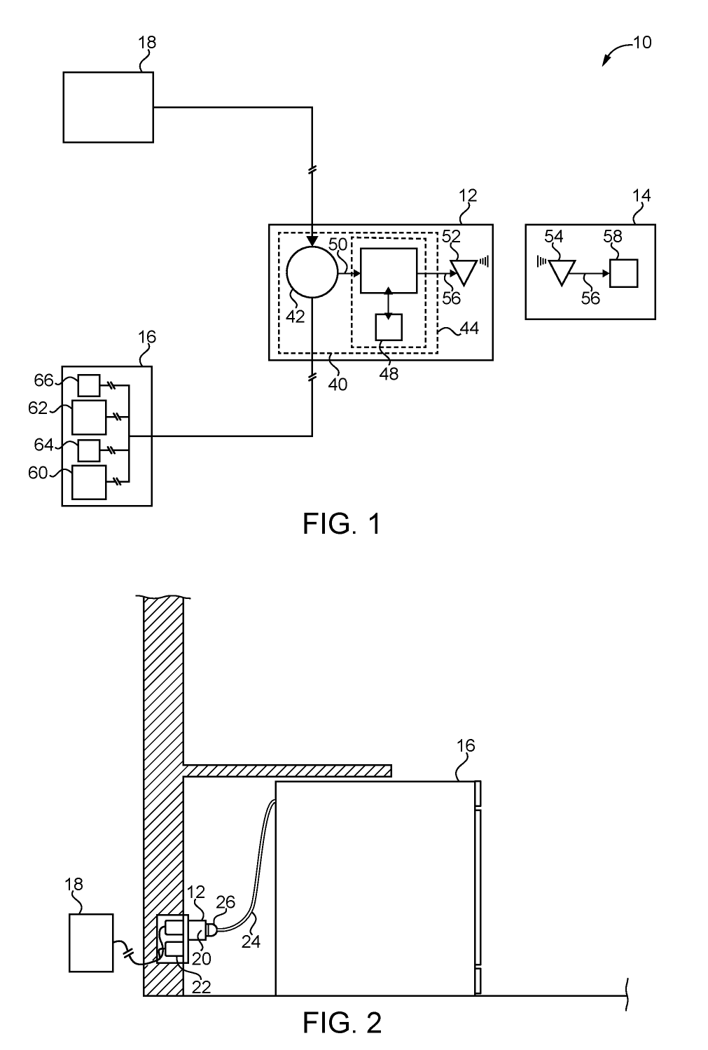

Referring now to FIG. 1, a block diagram of an appliance monitoring system (“system”) 10 for monitoring an operating state of an appliance 16 and producing a responsive alarm notification is shown. System 10 includes a plug-through monitoring device (“monitoring device”) 12 positioned in electric series between appliance 16 and a power source 18, and an alarm 14 communicatively coupled with monitoring device 12. Appliance 16 could be any electrically powered household appliance, such as a washing machine, dryer, dishwasher, coffee pot, iron, electric oven, electric stove, toaster, slow cooker, or any other similar appliance structured to perform a task and that is powered by drawing electrical current from power source 18. In some embodiments, appliance 16 can be any other device or appliance used in a commercial, industrial, or other setting, provided of course such device or appliance can be powered by electrical current. System 10 is structured to monitor current draw by appliance 16 to detect a change in operating state of appliance 16 indicative of appliance 16 completing a task, and produce an alarm notification to alert a user.

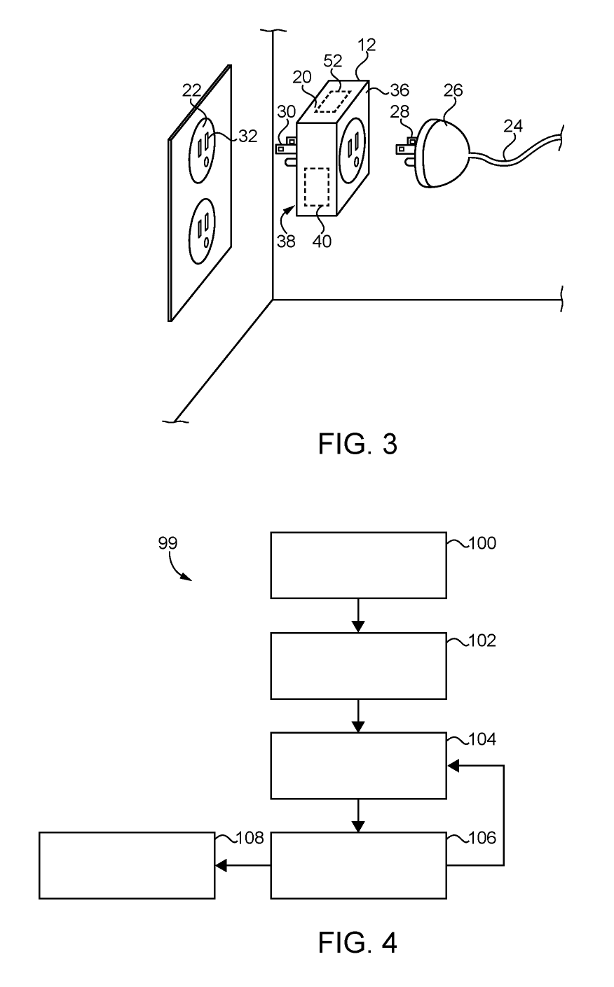

Referring now also to FIG. 2, a partially sectioned diagrammatic view of a portion of system 10 illustrating the relative positioning of appliance 16, monitoring device 12, and power source 18 is shown according to one embodiment. In the present embodiment of system 10, appliance 16 includes a dishwasher. Appliance 16 includes a power cord 24 extending therefrom, and terminates at a plug 26 having one or more prongs 28 structured to conduct electrical current to appliance 16, and that are configured to correspond with an orientation of one or more slots 32 included in an outlet 22. Plug 26 may also have a ground prong (not numbered). Outlet 22 is coupled with power source 18 and provides a terminal for accessing electrical current. Referring now also to FIG. 3, a close up view of a portion of system 10 is shown to illustrate an exemplary connection among outlet 22, monitoring device 12, and plug 26. Monitoring device 12 includes a housing 20 having a first side 36 and a second side 38, with one or more prongs 30 structured similar to prongs 28 positioned on first side 36, and one or more slots 34 structured similarly to slots 32 on second side 38. Slots 34 include electrical contacts similar to an electrical outlet. Monitoring device 12 may be a “plug-through” device in that prongs 30 and slots 34 allow monitoring device 12 to be plugged into outlet 22 and allow plug 26 to be plugged into monitoring device 12 such that electrical current may pass from power source 18 through monitoring device 12 to appliance 16. It will be appreciated that other plugs 28 and outlets 22 may have any number of different sizes, shapes, and configurations, include a different number or configuration of prongs 28 or slots 32. For example, the number, size, and orientation of plugs and slots often differs by country. Accordingly, alternative embodiments of monitoring device 12 may include prongs 30 and slots 34 structured to conform with any such variations. In still other embodiments, monitoring device 12 might include multiple corresponding sets of prongs 30 and slots 34, or might have multiple sets of slots 34 and only one set of prongs 30. For instance, monitoring device 12 might be in the form of a power strip or surge protector in that monitoring device 12 includes several sets of slots 34 and a single set of prongs 30.

As can be seen in FIG. 1, monitoring device 12 may include an electrical monitoring mechanism 40 resident in house 20 and structured to detect a change in current draw pattern indicative of current draw by appliance 16. Electrical monitoring mechanism 40 includes a sensor 42 or current probe structured to monitor electrical current draw by appliance 16 from power source 18, and output a current signal 50 indicative of an amplitude of current draw by appliance 16. Device 12 includes internal circuitry electrically connecting prongs 30 and slots (contacts) 34, for conducting electrical current between power source 18 and appliance 16. Sensor 42 is in electrical contact with the internal circuitry. Electrical monitoring mechanism 40 might also include an electronic control unit (ECU) 44, which may further include a processor (central processing unit) 46 and a computer readable memory 48. Processor 46 may be structured to receive current signal 50 from sensor 42, although in some embodiments, processor 46 may additionally or alternatively be structured to interrogate sensor 42 to produce data indicative of current draw, namely amplitude. Memory 48 may store processor executable instructions that, when executed by processor 46, cause processor 46 to perform one or more processes configured to monitor current signal 50 to determine the operating state of appliance 16. In some embodiments, memory 48 may include other data or instructions, such as, for example, a searchable array of threshold current levels that are indicative of a change in the operating state for a variety of different appliances 16. In alternative embodiments, electrical monitoring mechanism 40 may include an analog, digital, or mixed-signal electronic circuit structured to monitor current draw.

Monitoring device 12 may further include a transmitter 52 communicatively positioned between processor 46 and a receiver 54 in alarm 14 such that transmitter 52 may receive an alarm signal 56 from processor 46 and then transmit the alarm signal 56 to receiver 54. In some embodiments, system 10 could include a single alarm 14 communicatively coupled with two or more monitoring devices 12, or a single monitoring device 12 could be coupled with two or more alarms 14. Both transmitter 52 and receiver 54 may include antenna (not pictured) and/or other components that may enable transmitter 52 to send a wireless alarm signal 56 to receiver 54. The wireless signal might be performed using technologies such as, by way of example, WiFi (IEEE 802.11a/b/g/n/ac) technology, Bluetooth technology, IEEE 802.15.4 or Zigbee technology, or cellular technology, and/or may be in the form of an RF signal, IR signal, ultrasonic signal, or infrasonic signal, to name a few examples. In some embodiments, transmitter 52 may be coupled to alarm 14 by a wired or any other type of connection. Alarm 14 includes an alarm notification mechanism 58 structured to produce an audible, visual, tactile, and/or other type of alarm notification for alerting users to a change in the operating state. For instance, alarm notification mechanism 58 may include a speaker or a light. In other embodiments, transmitter 52 may be structured to transmit alarm signal 56 to an off-site server or database via the internet or cellular network, which may then send alarm signal 56 to receiver 54 and/or alarm 14. In some embodiments, alarm 14 may include a mobile device, computer, smart home bridge or receiver, or other electronic hardware capable of receiving alarm signal 56 and producing an alarm notification or otherwise producing a signal capable of triggering an alarm notification. In still other embodiments, monitoring device 12 may be structured to transmit current signal 50 to a server or database for monitoring current draw by appliance 16 and outputting alarm signal 56 responsive to data indicative of a change in the operating state. As used herein, monitoring “current draw” means monitoring the presence, absence, amplitude, or rate of change in amplitude. Higher order characteristics of electrical current flow through device 12 could also be exploited.

Referring now also to FIG. 4, a flowchart 99 illustrating exemplary process control and logic for monitoring an operating state of appliance 16 is shown. As mentioned above, appliance 16 may be structured to perform one or more tasks. For instance, a dishwasher is structured to perform the task of washing and drying dishes. The operating state of appliance 16 may be indicative of running one or more tasks. Appliance 16 may have two or more operating states, including an “ON” operating state during which appliance 16 may draw current to energize one or more internal components to perform the desired task, and an “idle” operating state during which appliance 16 may not be performing the desired task and may thus draw less current than when in the ON operating state. In this way, the operating state of appliance 16 or a change in the operating state of appliance 16 may correspond with a change in current draw by appliance 16. As such, to determine the operating state of appliance 16, processor 46 may receive data indicative of current draw by appliance 16 at block 100, by, for example, receiving current signal 50.

One of skill in the art will appreciate that changes in current draw of a certain magnitude are more likely to indicate a change in the operating state than lesser changes in current draw. Put differently, larger variations in current draw may be more likely to correspond with beginning or completing a task than small changes will be. Typically, household appliances will include a variety of electrically powered internal components. Some components may be primary components structured to perform or assist in the performance of one or more tasks, like a motor or a heater, for instance. Primary components often require more electrical current to operate than auxiliary components, such as lights or digital displays, that may be structured to perform secondary functions that may or may not be associated with running a task. As can be seen in FIG. 1, appliance 16 may have a first primary component 60, a second primary component 62, a first auxiliary component 64, and a second auxiliary component 66. In other embodiments, appliance 16 may include any other number of primary components 60, 62 or auxiliary components 64, 66. Total current draw by appliance 16 at any given time may therefore be indicative of whether one or more primary components 60, 62 are running, which may in turn provide information about the operating state of appliance 16. For example, running a task often necessitates energizing at least one primary component 60, 62, which may require more electrical power than might be required for energizing auxiliary components 64, 66 alone. Electrical monitoring mechanism 40 may therefore be structured to detect changes in current draw indicative of energization of one or more primary components 60, 62. Put differently, electrical monitoring mechanism 40 may monitor a pattern of current draw for increases above a determined threshold current level that exceeds an expected current draw by auxiliary components 64, 66 alone, and for subsequent decreases in current draw that drop below the threshold current level. The threshold current level may be determined by processor 46 according to executable instructions. An increase in current draw that exceeds the threshold current level may indicate a first change in the operating state which may be understood as a change from the idle operating state to the ON operating state. In this way, electrical monitoring mechanism 40 may be able to differentiate a change in current draw associated with a change in the operating state with a change in current draw associated with, for instance, turning on a light in a dryer, or setting a timer on an oven or stove. As such, electrical monitoring mechanism 40 may monitor current signal 50 to detect an increase in current draw indicative of a first change in the operating state at block 102.

In some embodiments, the threshold current level may be determined from prior measurements by sensor 42 or any other measurements or parameters, or may be predetermined and stored in memory 48. In an alternative embodiment, electrical monitoring mechanism 40 may be structured to monitor current draw for a time after the increase to detect a decrease in current draw that may indicate appliance 16 is not running a task. In other embodiments, electrical monitoring mechanism 40 may monitor current draw increase of a certain magnitude as compared with a prior operating state. For example, in some embodiments, a two- to four-fold increase in current draw may be indicative of a change in the operating state. In still other embodiments, electrical monitoring mechanism 40 could be structured to receive data from other devices and/or generate alarm signal 56 upon the occurrence of a different event or series of events, such as, for example, completing a timed countdown triggered upon detecting a current increase, or producing alarm signal 56 only if electrical monitoring system 40 receives GPS data indicating a user has left a predefined area.

Ending a task may include deenergizing one or more primary components 60, 62, which may correspond with a drop in current draw below the threshold current level. A drop in current draw below the threshold current level may therefore be indicative of a second change in the operating state, which may be understood as a change from the ON operating state to the idle operating state. As such, electrical monitoring mechanism 40 may monitor current signal 50 to detect a decrease in current draw that might be indicative of the second change in the operating state at block 104.

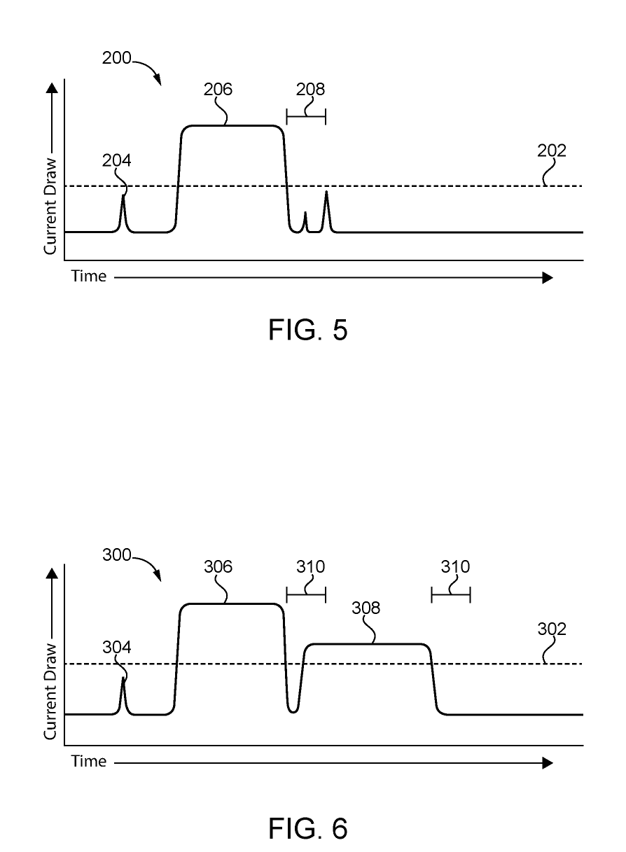

Execution of a task may include appliance 16 running one or more cycles, wherein a “cycle” may be understood to mean the selective energization of one or more internal components 60, 62, 64, 66 of appliance 16 to perform a process or action. Some tasks may include running only a single cycle, while others may include running multiple cycles concurrently. Still others, however, may run multiple cycles in succession. As will be explained further in the discussion of FIGS. 5 and 6 hereinafter, a single crossing of the threshold current level may not indicate a change in the operating state in some instances and thus, electrical monitoring mechanism 40 may be structured to continue monitoring current draw after detecting a decrease in current draw at block 106. Electrical monitoring mechanism 40 may be structured to continue monitoring current draw for a predetermined period of time after current draw crosses the threshold current level (hereinafter the “look back period”). In other embodiments, the length of the look back period may not be predetermined, and may be responsive to, for example, a user inputting a look back parameter value or determining another parameter, or may be determined completely independent of any fixed parameter. An increase in current draw above the threshold current level during the look back period may indicate the prior decrease in current draw was not indicative of a second change in the operating state. As such, if electrical monitoring mechanism 40 detects an increase in current draw during the look back period, electrical monitoring mechanism 40 may continue monitoring current signal 50 to detect a decrease in current draw that could be indicative of the second change in the operating state at block 104. If, however, electrical monitoring mechanism 40 does not detect an increase in current draw above the threshold current level during the look back period, electrical monitoring mechanism 40 may output alarm signal 56 responsive to the second change in the operating state at block 108. In other embodiments, electrical monitoring mechanism 40 may monitor changes in current draw relative to another parameter, such as a maximum or minimum current draw, or current draw associated with a prior operating state. For example, electrical monitoring mechanism 40 may be structured to detect a decrease in current draw that is at least a majority of the current draw in the present operating state, in a prior operating state, or of the maximum current draw.

Referring now to FIGS. 5 and 6, two graphs illustrating exemplary current draw patterns for two types of appliances are illustrated according to one embodiment. In both FIGS. 5 and 6, a plug-through monitoring device including an electrical monitoring mechanism may monitor a current draw pattern indicative of an amount of current draw by the appliance relative to a threshold current level to detect changes in an operating state of an appliance, which may be identical to appliance 16. FIG. 5 shows an exemplary current draw pattern 200 for an appliance structured to perform a single task. The task may be associated with a single cycle task, or may be associated with a task that includes multiple concurrent cycles. For example, the appliance may include a dryer or a toaster. For appliances such as these, current draw pattern 200 might consist of a single spike that crosses a threshold current level 202. As seen in FIG. 5, a first spike 204 in current pattern 200 fails to cross threshold current level 202, which may mean first spike 204 is associated with energization of one or more auxiliary components. As such, the increase in current draw that corresponds with first spike 204 may not indicate a change in the operating state. A second spike 206 in current draw does cross threshold current level 202, however, which may indicate a change in the operating state. More particularly, current draw pattern 200 exceeding threshold current level 202 may be indicative of a first change in the operating state. Current draw pattern 200 later drops below threshold current level 202, which might be indicative of a second change in the operating state. Indeed, current draw pattern 200 subsequently fails to cross threshold current level 202 during a look back period 208, which may trigger an alarm notification consistent with the present disclosure.

Referring now to FIG. 6, an exemplary current draw pattern 300 for an appliance structured to perform a task by running two successive cycles, or perform two successive tasks is shown. For example, the appliance may include a dishwasher that includes a wash cycle followed by a dry cycle. In other embodiments, the appliance may run more than two successive cycles or tasks. For appliances such as these, current draw pattern 300 may include at least two successive spikes in current draw that cross a threshold current level 302. Current draw pattern 300 is similar to current draw pattern 200 in that a first spike 304 in current draw fails to cross threshold current level 302 but a second spike 306 in current draw does cross threshold current level 302, which may be indicative of a first change in the operating state. Unlike current draw pattern 200, however, current draw pattern 300 has a third current draw spike 308 within a look back period 310 after second current draw spike 306 drops below threshold current level 302. In this embodiment, a plug-through monitoring device including an electrical monitoring mechanism may continue to monitor current draw pattern 300 for another drop below threshold current level 302. Third spike 308 later drops below threshold current level 302, and threshold current level 302 is not crossed during another look back period 310, which may trigger an alarm notification consistent with the present disclosure. In other embodiments, current draw pattern 300 may have any number of subsequent spikes in current level.

The present description is for illustrative purposes only, and should not be construed to narrow the breadth of the present disclosure in any way. Thus, those skilled in the art will appreciate that various modifications might be made to the presently disclosed embodiments without departing from the full and fair scope and spirit of the present disclosure. It will be appreciated that certain features and/or properties of the present disclosure, such as relative dimensions or angles, may not be shown to scale. As noted above, the teachings set forth herein are applicable to a variety of different appliances having a variety of different structures than those specifically described herein. Other aspects, features and advantages will be apparent upon an examination of the attached drawings and appended claims. As used herein, the articles “a” and “an” are intended to include one or more items, and may be used interchangeably with “at least one.” Where only one item is intended, the term “one” or similar language is used. Also, as used herein, the terms “has,” “have,” “having,” or the like are intended to be open-ended terms

What is claimed is:

1. A method for monitoring an operating state of an appliance, the method comprising:
detecting an increase in current draw indicative of a first change in the operating state;
detecting a decrease in current draw indicative of a second change in the operating state that is indicative of the appliance completing a task;
monitoring current draw after detecting the decrease in current draw; and
outputting an alarm signal responsive to the second change in the operating state.

2. The method of claim 1 wherein detecting an increase in current draw includes detecting current draw in excess of a threshold current level.

3. The method of claim 1 wherein detecting a decrease in current draw includes detecting a decrease in current draw below a threshold current level, and monitoring current draw after the decrease in current draw further includes determining the current draw is below the threshold current level.

4. The method of claim 1 wherein detecting a decrease in current draw includes detecting a decrease in current draw that is at least a majority of current draw in a prior operating state.

5. The method of claim 1 wherein the steps are performed by a plug-through device.

6. The method of claim 5 further comprising generating an alarm notification at a receiver separate from the plug-through device responsive to the alarm signal.

7. A system for detecting changes to an operating state in an appliance comprising:
a plug-through device positioned in electric series between the appliance and a power source, the plug-through device including an electrical monitoring mechanism structured to detect a current draw pattern indicative of a change in current draw by the appliance, and output an alarm signal responsive to the current draw pattern; and
an alarm including an alarm notification mechanism that activates responsive to the alarm signal.

8. The system of claim 7 wherein the electrical monitoring mechanism is further structured to detect a current draw pattern indicative of a first change in the operating state, detect a current draw pattern indicative of a second change in the operating state, and output the alarm signal responsive to the current draw pattern indicative of the second change in the operating state.

9. The system of claim 7 wherein the electrical monitoring mechanism is further structured to detect a current draw pattern indicative of current draw by a component of the appliance.

10. The system of claim 7 wherein the electrical monitoring mechanism includes an electronic control unit structured to:
receive data indicative of current draw;
determine the operating state of the appliance; and
output the alarm signal.

11. The system of claim 10 further including a wireless transmitter structured to wirelessly transmit the alarm signal.

12. The system of claim 10 wherein the electrical monitoring mechanism includes a sensor configured to monitor current draw by the appliance.

13. A plug-through device for determining an operating state of an appliance comprising:
a housing including a first side and a second side;
a prong extending from the first side;
a slot positioned on the second side;
an electric monitoring mechanism resident in the housing and structured to detect a change in current draw by the appliance indicative of a change in the operating state of the appliance, and to output an alarm signal responsive to the change in current draw; and
a transmitter structured to transmit the alarm signal.

14. The device of claim 13 wherein the electric monitoring mechanism includes a sensor structured to monitor current draw by the appliance, and an electronic control unit structured to receive data indicative of current draw by the appliance, the electronic control unit including a processor, and a memory storing processor executable instructions that, when executed by the processor, cause the processor to:
monitor data indicative of current draw for an increase in current draw indicative of a first change in the operating state;
monitor data indicative of current draw for a decrease in current draw indicative of a second change in the operating state; and
monitor current draw after the decrease in current draw indicative of the second change in operating state.

15. The device of claim 14 wherein the executable instructions, when executed by the processor, further cause the processor to determine a threshold current level indicative of the operating state.

16. The device of claim 14 wherein an increase in current draw indicative of the second change in the operating state includes an increase in current draw above a threshold current level, and a decrease in current draw indicative of the second change in the operating state includes a decrease in current draw below the threshold current level.
